(19) United States
(12) Patent Application Publication
(10) Pub. No.: US 2026/0271748 A1
(43) Pub. Date: Sep. 10, 2026

(54) FULLY ISOLATED SUPER VIA IN WAFER STACKING STRUCTURE

(71) Applicant: Applied Materials, Inc., Santa Clara, CA (US)

(72) Inventors: Tyler SHERWOOD, Fonda, NY (US); Athena PANG, San Jose, CA (US); Jeremiah HEBDING, East Berne, NY (US)

(21) Appl. No.: 19/071,696

(22) Filed: Mar. 5, 2025

(51) Int. Cl. H01L 23/538; H01L 21/768; H01L 23/498

(52) U.S. Cl. CPC H10W 70/611; H10W 20/057; H10W 20/076; H10W 20/081; H10W 70/635; H10W 90/701

(57) ABSTRACT

A method of forming a fully isolated super via in wafer stacking structure includes performing a metal passivation process to passivate exposed sidewalls of bonding pads within a super via formed through a multi-wafer stacking structure with a passivation layer, the multi-wafer stacking structure comprising the bonding pads, bond layer interfaces, dielectric layers encapsulating the bonding pads and the bond layer interfaces, and silicon layers covering the dielectric layers, performing a selective deposition process to form an insulator layer on sidewalls of the silicon layers, the dielectric layers, and the bond layer interfaces within the super via, performing a clean process to remove the passivation layer, and performing a metallization process to fill the super via with contact metal material.

### BACKGROUND

### Field

Embodiments described herein generally relate to semiconductor device fabrication, and more particularly, to forming a through-silicon via in a multi-wafer stacking structure.

### Description of the Related Art

Traditionally, through-silicon via (TSV) architecture requires formation of vias at each wafer stack, and subsequently bonding wafers in a multi-wafer stacking structure. This process includes multiple patterning for forming vias, isolation of the vias, and metallization for forming metal line and side-contacts in the vias at each wafer stack, and subsequently aligning the vias while bonding multiple wafers.

Deep super via structures connecting metal lines through multiple wafers and bond interfaces are required for advanced packaging architectures. However, in addition to the difficultly in aligning and etching these deep complex structures, the isolation of the via in parallel with the side-contact metallization has technical challenges. For example, forming a dielectric material (e.g., silicon oxide (SiO₂)) on inner sidewalls of a deep super via is temperature constrained and often involves an oxygen source, and thus also oxidizes exposed surfaces of metal side-contacts.

Therefore, there is a need for methods for overcoming such challenges in deep super via structures.

### SUMMARY

Embodiments of the present disclosure provide a method of forming a fully isolated super via in wafer stacking structure. The method includes performing a metal passivation process to passivate exposed sidewalls of bonding pads within a super via formed through a multi-wafer stacking structure with a passivation layer, the multi-wafer stacking structure comprising the bonding pads, bond layer interfaces, dielectric layers encapsulating the bonding pads and the bond layer interfaces, and silicon layers covering the dielectric layers, performing a selective deposition process to form an insulator layer on sidewalls of the silicon layers, the dielectric layers, and the bond layer interfaces within the super via, performing a clean process to remove the passivation layer, and performing a metallization process to fill the super via with contact metal material.

Embodiments of the present disclosure also provide a method of forming a metal side-contact within a via. The method includes passivating a metal surface of inner sidewalls of a via with a passivation layer, depositing an insulator layer selectively on the remaining non-metal surfaces of the inner sidewalls of the via, removing the passivation layer, and forming a metal side-contact on the metal surface.

Embodiments of the present disclosure further provide a multi-wafer stacking structure. The multi-wafer stacking structure includes a stack of bond layer interfaces in a first direction, bonding pads on both sides of each of the bond layer interfaces, dielectric layers encapsulating the bonding pads and the bond layer interfaces, silicon layers covering the dielectric layers, a super via formed through the bonding pads, an insulator layer on sidewalls of the silicon layers, the dielectric layers, and the bond layer interfaces within the super via, and a metal line and a metal side-contact within the super via, wherein the metal line is electrically connected to the bonding pads via the metal side-contacts and isolated from the bond layer interfaces.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 is a cross-sectional view of a portion of a multi-wafer stacking structure that includes a through-silicon via (TSV), according to one or more embodiments of the present disclosure.

FIG. 3 depicts a process flow diagram of a method of forming a through-silicon via (TSV) in a multi-wafer stacking structure, according to one or more embodiments of the present disclosure.

FIGS. 4A, 4B, 4C, and 4D are cross-sectional views of a portion of a multi-wafer stacking structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming a fully isolated super via in a wafer stacking structure. The methods described herein include a single etch operation to form a super via through a stack of wafers and forming an insulator layer on inner sidewalls of the entire super via while masking exposed metal surfaces. A masking layer inhibits growth of the insulator on the metal surfaces and further protects the metal surfaces from oxidation during the deposition of the insulator layer on non-metal surfaces.

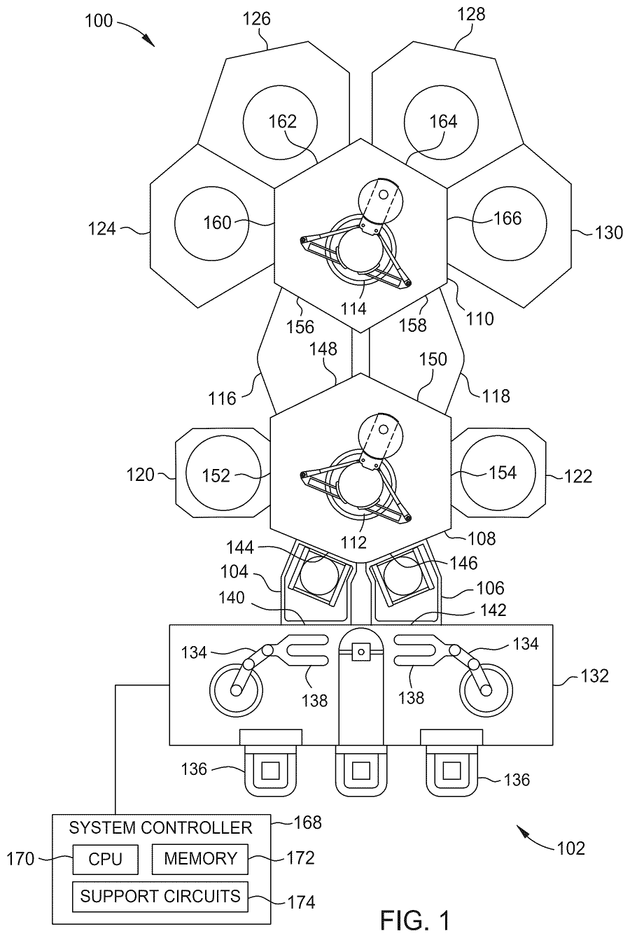

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

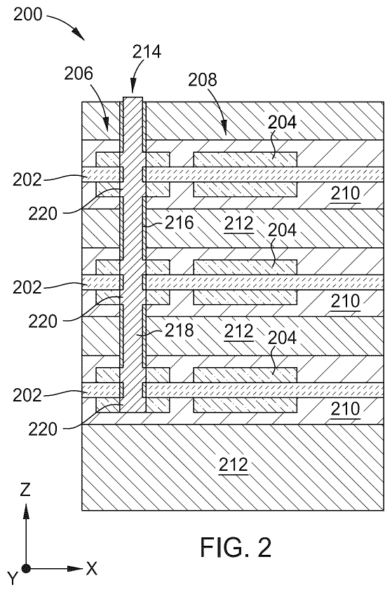

FIG. 2 is a cross-sectional view of a portion of a multi-wafer stacking structure 200 that includes a through-silicon via (TSV), according to one or more embodiments of the present structure. The multi-wafer stacking structure 200 includes a stack of bond layer interfaces 202 in the Z direction. Each bond layer interface 202 has bonding pads 204 disposed on both sides and aligned in the Z direction. A first stack 206 of the bonding pads 204 and a second stack 208 of the bonding pads 204 are shown. The bonding pads 204 and the bond layer interfaces 202 are encapsulated within dielectric layers 210. The dielectric layers 210 are covered by silicon layers 212. The multi-wafer stacking structure 200 may be formed by wafer-to-wafer hybrid bonding.

The bond layer interfaces 202 may be formed of silicon oxide (SiO₂), silicon nitride (Si₃N₄), or other dielectric, each having a thickness of between about 2 nm and about 10 nm. The bonding pads 204 may be formed of metal, such as copper (Cu), aluminum (Al), tungsten (W), or molybdenum (Mo), each having a thickness of between about 15 nm and about 2 μm, a width of between about 15 nm and about 5 μm, and a pitch between adjacent bonding pads 204 of between about 10 nm and about 30 nm.

The dielectric layers 210 may be formed of silicon oxide (SiO₂), silicon nitride (Si₃N₄), silicon carbon nitride (SiCN), or aluminum nitride (AlN). The silicon layers 212 may be formed of silicon (Si), such as thinned and infused substrates.

Through the first stack 206 of the bonding pads 204, a through silicon via (TSV) (also referred to as a “super via”) 214 is formed by appropriate etching, subsequent to the wafer-to-wafer hybrid bonding. The TSV 214 may have a critical dimension (CD) of between about 0.3 μm and about 10 μm. Within the TSV 214, an insulator layer 216 is formed on inner sidewalls of the TSV 214 except for sidewalls of the bonding pads 204. Further within the TSV 214, a metal line 218 and metal side-contacts 220 are formed. The metal line 218 is electrically connected to the bonding pads 204 via the metal side-contacts 220 and isolated from the bond layer interfaces 202.

The term “substrate” as used herein refers to a layer of material that serves as a basis for subsequent processing operations and includes a surface to be cleaned. The substrate may be a silicon-based material or any suitable insulating materials or conductive materials as needed. The substrate may include a material such as crystalline silicon (e.g., Si<100>, Si<110>, or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

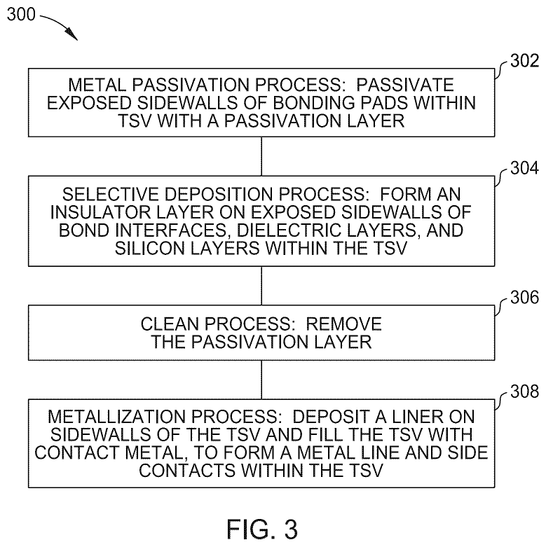

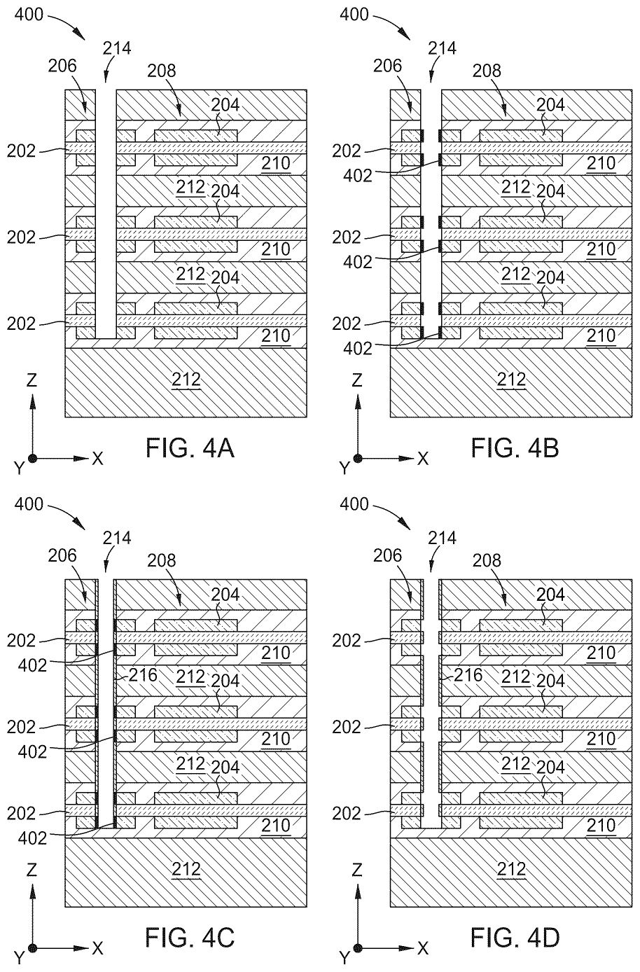

FIG. 3 depicts a process flow diagram of a method 300 of forming a through-silicon via (TSV) in a multi-wafer stacking structure 400 that may form the multi-wafer stacking structure 200, according to embodiments of the present disclosure. FIGS. 4A, 4B, 4C, and 4D are cross-sectional views of a portion of the multi-wafer stacking structure 400, corresponding to various states of the method 300. It should be understood that FIGS. 4A, 4B, 4C, and 4D illustrate only partial schematic views of the multi-wafer stacking structure 400, and the multi-wafer stacking structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

As shown in FIG. 4A, the multi-wafer stacking structure 400 includes a stack of bond layer interfaces 202 in the Z direction. Each bond layer interface 202 has bonding pads 204 disposed on both sides and aligned in the Z direction. A first stack 206 of the bonding pads 204 and a second stack 208 of the bonding pads 204 are shown in FIG. 4A. The bonding pads 204 and the bond layer interfaces 202 are encapsulated within dielectric layers 210. The dielectric layers 210 are covered by silicon layers 212. The multi-wafer stacking structure 400 may be formed by wafer-to-wafer hybrid bonding.

Through the first stack 206 of the bonding pads 204, a through silicon via (TSV) (also referred to as a “super via”) 214 is formed by a single etch step, subsequent to the wafer-to-wafer hybrid bonding. Within the TSV 214, sidewalls of the bonding pads 204 are exposed.

The method 300 begins with block 302, in which a metal passivation process is performed to passivate the exposed sidewalls of the bonding pads 204 (e.g., metal surfaces) within the TSV 214 with a passivation layer 402, as shown in FIG. 4B.

The passivation layer 402 may be formed of a self-assembled monolayer (SAM) or a self-assembled multilayers of amphiphilic organic molecules, such as alkylphosphonic acids (PAs), including n-octadecylphosphonic acid ((C₁₈H₃₉O₃P), ODPA), n-dodecylphosphonic acid (C₁₂PA), n-decylphosphonic acid (C₁₀PA), or n-octylphosphonic acid (C₈PA). Such PAs are known to be absorbed on metal surfaces (e.g., copper (Cu)).

The metal passivation process may be a CVD soaking process, performed in a CVD chamber, a thermal processing chamber, a plasma chamber, or a radical chamber, such as the processing chamber 124, 126, 128, or 130 shown in FIG. 1.

The passivation layer 402 may suppress deposition of insulator material thereon during a subsequent deposition process, and thus allow selective deposition of insulator material on remaining non-metal surfaces within the TSV 214. The passivation layer 402 may further protect the surfaces of the bonding pads 204 from oxidation during the subsequent deposition process.

In block 304, a selective deposition process is performed to form an insulator layer 216 selectively on exposed sidewalls of the silicon layers 212, the dielectric layers 210, and the bond layer interfaces 202 (e.g., the remaining non-metal surfaces) within the TSV 214, as shown in FIG. 4C. The insulator layer 216 is inhibited on the passivation layer 402.

The insulator layer 216 may be formed of a high-k material (e.g., aluminum oxide (Al₂O₃), hafnium oxides (HfO₂), or hafnium zirconium oxide (HfZrO₂)) or silicon oxide (SiO2), or Silicon Nitride having a thickness of between about 30 nm and about 0.5 μm.

The selective deposition process may include atomic layer deposition (ALD), performed in a processing chamber, such as the processing chamber 126, 128, or 130 shown in FIG. 1.

In block 306, a clean process is performed to remove the passivation layer 402, as shown in FIG. 4D. The clean process may include ashing using diazene (N₂H₂).

In block 308, a metallization process is performed to deposit a conformal liner on exposed sidewalls of the TSV 214 and fill the TSV 214 with contact metal material, such as copper (Cu), tungsten (W), cobalt (Co), ruthenium (Ru), or molybdenum (Mo), to form a metal line 218 and metal side-contacts 220 within the TSV 214 and arrive the multi-wafer stacking structure 200, as shown in FIG. 2. The metal side-contacts 220 are formed where the passivation layer 402 is removed. The metal line 218 is electrically connected to the bonding pads via the metal side-contacts 220 and isolated from the bond layer interfaces 202.

The liner may be formed of tantalum nitride (TaN), titanium nitride (TiN), titanium aluminum carbide (TiAlC), tungsten nitride (WN), tungsten (W), cobalt (Co), or ruthenium (Ru).

A deposition process to deposit the liner may include any appropriate deposition process, such as atomic layer deposition (ALD), chemical vapor deposition (CVD), or physical vapor deposition (PVD), performed in a processing chamber, such as the processing chamber 126, 128, or 130 shown in FIG. 1. A metal filling process to fill the TSV 214 with contact metal material may include seeding to form a metallic seed layer, electroplating, chemical vapor deposition (CVD) process using a tungsten-containing precursor, such as WF₆, or a cobalt-containing precursor, in a processing chamber, such as the processing chamber 126, 128, or 130 shown in FIG. 1. [Inventors: Please revise metal filling process details as appropriate.] After the metal filling process, the multi-wafer stacking structure 400 may be planarized.

The embodiments described herein provide methods for forming a fully isolated super via in wafer stacking structure. The methods described herein include a single etch step to form a super via through a stack of wafers and forming an insulator layer on inner sidewalls of the entire super via while masking exposed metal surfaces. A passivation layer formed on metal surfaces prior to the forming of the insulator layer inhibits growth of the insulator on the metal surfaces and further protects the metal surfaces from oxidation during the deposition of the insulator layer on non-metal surfaces.

While the foregoing is directed to embodiments of the present disclosure, other and further embodiments of the disclosure may be devised without departing from the basic scope thereof, and the scope thereof is determined by the claims that follow.

1. A method of forming a fully isolated super via in wafer stacking structure, comprising:
performing a metal passivation process to passivate exposed sidewalls of bonding pads within a super via formed through a multi-wafer stacking structure with a passivation layer, the multi-wafer stacking structure comprising the bonding pads, bond layer interfaces, dielectric layers encapsulating the bonding pads and the bond layer interfaces;
performing a selective deposition process to form an insulator layer on sidewalls of the dielectric layers and the bond layer interfaces within the super via;
performing a clean process to remove the passivation layer; and
performing a metallization process to fill the super via with contact metal material.

2. The method of claim 1, where the bonding pads comprise copper (Cu), aluminum (Al), tungsten (W), or molybdenum (Mo), the dielectric layers comprise silicon oxide (SiO₂), silicon nitride (Si₃N₄), silicon carbon nitride (SiCN), or aluminum nitride (AlN).

3. The method of claim 1, wherein the passivation layer comprises a self-assembled monolayer (SAM) of n-octadecylphosphonic acid ((C₁₈H₃₉O₃P), ODPA).

4. The method of claim 1, wherein the selective deposition process comprises atomic layer deposition (ALD).

5. The method of claim 1, wherein the insulator layer comprises aluminum oxide (Al₂O₃) hafnium oxides (HfO₂), hafnium zirconium oxide (HfZrO₂), or silicon oxide (SiO2).

6. The method of claim 1 wherein the clean process comprises ashing using diazene (N₂H₂).

7. The method of claim 1, wherein:
the multi-wafer stacking structure further comprises silicon layers covering the dielectric layers, the silicon layers comprising silicon (Si), and
the selective deposition process further forms the insulator layer on sidewalls of the silicon layers.

8. The method of claim 1, further comprising:
subsequent to the clean process, depositing a liner on exposed sidewalls of the super via, by atomic layer deposition (ALD),
wherein the liner comprises tantalum nitride (TaN).

9. The method of claim 1, wherein the contact metal material comprises copper (Cu), tungsten (W), cobalt (Co), ruthenium (Ru), or molybdenum (Mo).

10. A method of forming a metal side-contact within a via, comprising:
passivating a metal surface of inner sidewalls of a via with a passivation layer;
depositing an insulator layer selectively on the remaining non-metal surfaces of the inner sidewalls of the via;
removing the passivation layer; and
forming a metal side-contact on the metal surface.

11. The method of claim 10, wherein the metal surface comprises copper (Cu), aluminum (Al), tungsten (W), or molybdenum (Mo), and the remaining non-metal surfaces comprise silicon oxide (SiO₂), silicon nitride (Si₃N₄), silicon carbon nitride (SiCN), or aluminum nitride (AlN).

12. The method of claim 10, wherein the passivation layer comprises a self-assembled monolayer (SAM) of n-octadecylphosphonic acid ((C₁₈H₃₉O₃P), ODPA).

13. The method of claim 10, wherein depositing the insulator layer comprises atomic layer deposition (ALD).

14. The method of claim 10, wherein the insulator layer comprises aluminum oxide (Al₂O₃), hafnium oxides (HfO₂), hafnium zirconium oxide (HfZrO₂), or silicon oxide (SiO2).

15. The method of claim 10, wherein the metal side-contact comprises copper (Cu), tungsten (W), cobalt (Co), ruthenium (Ru), or molybdenum (Mo).

16. A multi-wafer stacking structure, comprising:
a stack of bond layer interfaces in a first direction;
bonding pads on both sides of each of the bond layer interfaces;
dielectric layers encapsulating the bonding pads and the bond layer interfaces;
a super via formed through the bonding pads;
an insulator layer on sidewalls of the dielectric layers and the bond layer interfaces within the super via; and
a metal line and a metal side-contact within the super via, wherein the metal line is electrically connected to the bonding pads via the metal side-contacts and isolated from the bond layer interfaces.

17. The multi-wafer stacking structure of claim 16, further comprising:
silicon layers covering the dielectric layers.

18. The multi-wafer stacking structure of claim 16, wherein:
the super via has a critical dimension (CD) of between 0.3 μm and 10 μm,
the bond layer interfaces comprise silicon oxide (SiO₂) or silicon nitride (Si₃N₄), each having a thickness of between 2 nm and 10 nm,
the bonding pads comprise copper (Cu), aluminum (Al), tungsten (W), or molybdenum (Mo), each having a thickness of between 15 nm and 2 μm, a width of between 15 nm and 5 μm, and a pitch between adjacent bonding pads of between 10 nm and 30 nm.

19. The multi-wafer stacking structure of claim 16, wherein the insulator layer comprises aluminum oxide (Al₂O₃), hafnium oxides (HfO₂), hafnium zirconium oxide (HfZrO₂), or silicon oxide (SiO2).

20. The multi-wafer stacking structure of claim 16, wherein the metal line and the metal side-contact each comprise copper (Cu), tungsten (W), cobalt (Co), ruthenium (Ru), or molybdenum (Mo).
